(19) United States
(12) Patent Application Publication
(10) Pub. No.: US 2025/0044352 A1
(43) Pub. Date: Feb. 6, 2025

(54) USE OF A DATA SYMBOL ERROR BOUNDARY VIOLATION AS A TRIGGER SOURCE FOR SIGNAL CAPTURE AND STORAGE

(71) Applicant: Tektronix, Inc., Beaverton, OR (US)

(72) Inventor: Christopher N. White, Cedar Park, TX (US)

(21) Appl. No.: 18/779,763

(22) Filed: Jul. 22, 2024

Related U.S. Application Data
(60) Provisional application No. 63/516,638, filed on Jul. 31, 2023.

(51) Int. Cl. G01R 31/317; G01R 31/302

(52) U.S. Cl. CPC G01R 31/31708; G01R 31/3025

(57) ABSTRACT

A test and measurement instrument includes an antenna to receive signals containing symbols from a system under test (SUT), one or more analog-to-digital converters (ADC) to sample the signals received from the SUT, a memory to selectively store samples from the ADC, and one or more processors configured to execute code that causes the one or more processors to: receive samples from the ADC, analyze the samples from the ADC to determine whether one or more of the symbols received from the SUT has exceeded an expected modulation boundary for the one or more symbols; identifying a time at which the one or more symbols exceeded the expected modulation boundary as a trigger time; and store samples from a predetermined window of time surrounding the trigger time in the memory.

### CROSS-REFERENCE TO RELATED APPLICATIONS

This disclosure is a non-provisional of and claims benefit from U.S. Provisional Application No. 63/516,638, titled “USE OF A DATA SYMBOL ERROR VECTOR BOUNDARY VIOLATION AS A TRIGGER SOURCE FOR SIGNAL CAPTURE AND STORAGE,” filed on Jul. 31, 2023, the disclosure of which is incorporated herein by reference in its entirety.

### TECHNICAL FIELD

This disclosure relates to test and measurement instruments, and more particularly to identifying the moment when a cognitive communication system changes its mode of operation and using that moment as a trigger for the test and measurement instrument.

### BACKGROUND

In some RF system test use cases, like radio performance testing, especially for cognitive radio validation, message information is modulated onto the transmission signal and tests are performed to see how robust the system is against unwanted interference. When testing these systems under interference conditions, such as noise, indirect or direct jamming, and/or environmental interference, designers are testing how well the core radio design and cognitive engine responds and adapts to these interferers.

### BRIEF DESCRIPTION OF THE DRAWINGS

FIG. 1 shows an embodiment of a cognitive communication system testing environment.

FIG. 2 shows a trigger diagram for received symbols.

FIG. 3 shows a diagram demonstrating the impact of a jamming signal on a signal from a cognitive communication system.

### DESCRIPTION

Embodiments herein include devices and methods for improving the specificity of available triggering methods for validating communication systems. The term “communication systems” as used here means communication systems that communicate “over the air” using radio frequency (RF) signals. A “cognitive” communication system means a communication system that has an adaptive capability to adjust transmission characteristics like phase, amplitude, frequency, and signal modulation, to overcome interference conditions caused by jamming, noise, environmental interference, etc. The discussion here focuses on RF systems, but the embodiments may apply to any type of communication system that can suffer from signal impairments and adapts to account for the impairment.

When performing tests on cognitive communication systems, it is helpful to see the exact moment at which the radio becomes unable to communicate its intended payload, which is visible through a degradation of the modulation quality beyond a minimum level. The embodiments herein use the crossing of that level of insufficiency, where the modulation of the signal has degraded beyond the minimum level, as the trigger for acquisition of pre- and post-trigger samples that show the signal and the response of the system during the impacting event.

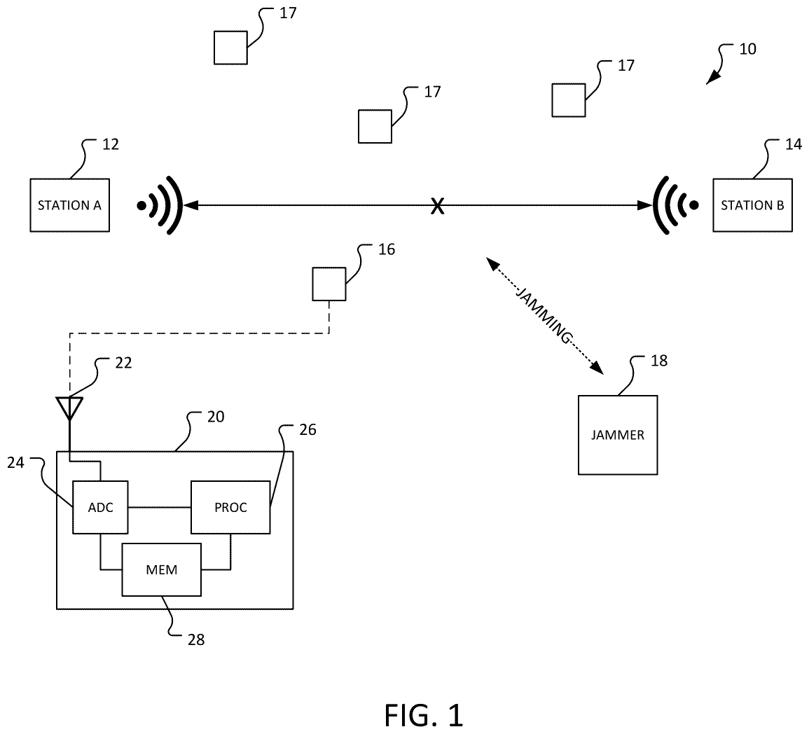

FIG. 1 shows an example of a test scenario with a test scenario having two radio prototypes, Station A 12, and Station B 14, communicating to each other in a cognitive communication system 10. Stations 12, 14 may comprise any device that can transmit RF signals, including traditional radios, cell phones, computers, as examples without limitation. An RF observation receiver also listens to the transmitting radio at Station A 12. As Station A 12 sends its communication, the observing RF receiver(s) continuously sample(s) the signal data.

The observation receiver may take the form of a sensor node, such as nodes 16, 17. The sensor nodes may reside at several locations around the system under test (SUT), in this example the radio system comprised of Station A 12, and Station B 14 . . . . The sensor nodes such as node 16 may comprise simple antennas/receivers that connect to a test and measurement instrument or may comprise a test and measurement device itself. The test and measurement instrument may comprise a spectrum analyzer, signal analyzer, or similar device, or a computer that has the ability to analyze signals. The sensor node 16 has an antenna to allow the receiver to receive the signals. The nodes that comprise test and measurement devices such as test and measurement device 20 may also have antennas such as antenna 22. If the test and measurement device 20 does not act as a sensor node, test and measurement device 20 may connect to sensor nodes such as node 16 across a network connection, as shown, or may also use radio communications itself.

If test and measurement instrument 20 acts as a sensor node, test and measurement instrument 20 receives the signals from the SUT at antenna 22. One or more analog-to-digital converters (ADC) such as ADC 24 may sample the signal at test and measurement device 20, or the sensor node 16 may include the ADC(s) that sample the signal and transmit them to the test and measurement device 20. The signal being received contains symbols. However the samples are generated, the sensor nodes such as node 16 may include a buffer that captures some number of samples in a first-in-first-out (FIFO) arrangement. Unless a triggering event occurs, the samples just enter and exit the buffer as the samples are received. Alternatively, the buffer may reside on the test and measurement instrument 20 as part of memory 28.

One or more processors, such as processor 26, are configured to execute code that causes the one or more processors to perform various tasks. The one or more processors analyze the samples to determine if one or more symbols in the signal are within a modulation boundary. Violations of the modulation boundary trigger the test and measurement device 20 to and store N samples prior to the trigger and M samples post-trigger in memory 28. If the samples reside on the sensor node such as node 16, the one or more processors may communicate with the node 16 to access the samples to be captured. Capturing only the samples around the boundary violation/trigger event reduces the number of samples for analysis. The user only needs to look at the window of samples defined by the N samples prior to the sample, the sample that causes the trigger, and the M samples post-trigger. Capturing only the window of samples also minimizes the amount of data to store, which simplifies a replay-search process on massive collections of data sets previously recorded.

The boundary, or threshold, that the one or more symbols violate to cause the trigger may take many forms. The user may define the boundary, or it may be defined by the communication standard under which the SUT operates. As mentioned above, the boundary comprises the point at which the radio performance is determined unusable. The point where the performance is determined unusable is also where the cognitive system adjusts its operating frequency or other operating parameters to avoid the impairment causing the boundary violation.

Boundaries may take the form of a threshold or band in which the received one or more symbols were expected to be received. The boundary violations may include deviation from expected phase, frequency and amplitude bands, or a defined measure such as the error vector magnitude (EVM). For ease of discussion, the following example uses EVM, without limitation.

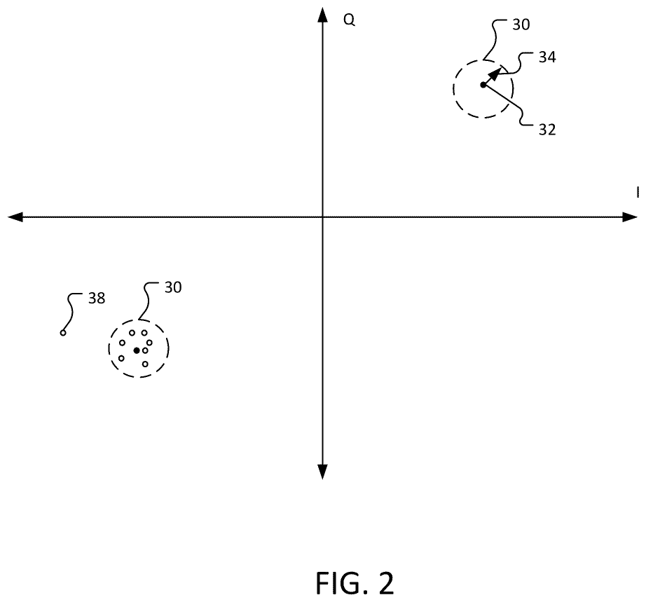

The EVM boundary trigger may be best understood by viewing the constellation diagram of the captured IQ data, such as the one shown in FIG. 2. Signal samples are converted to In-Phase and Quadrature (IQ) components and may be graphed on an I-Q plot. The signal characteristics are modulated in various ways to place the location of a point on this plot in places that represent digital information, defined as a “symbol.” The term “location” refers to a particular phase and amplitude of the signal, whether plotted or not. The example illustrated in FIG. 2 uses QPSK (Quadrature Phase Shift Keying) or 4QAM (4-Quadrature Amplitude Modulation). These modulation schemes use four distinct symbol locations, each representing two bits of information. In some embodiments, the IQ components may be plotted on an I-Q plot. The system may employ other types of modulation schemes, the above modulation schemes are merely examples.

For the processing algorithms to interpret a sample or samples as a particular symbol, the sample must fall within boundary 30 around the ideal symbol location 32. For ease of discussion, FIG. 2 uses EVM, also known as the minimum error vector. Error vector 34 is the vector difference between the actual sample and the ideal symbol location 32, in cartesian units of I and Q. As shown in upper right quadrant of FIG. 2, the boundary around the ideal symbol location 32 can be viewed as a circle with center at the ideal symbol location 32 and radius of the magnitude of the error vector 34. As shown in the lower left quadrant of FIG. 2, all the samples in the circle represent “good” modulation. A symbol sample such as sample 38 falls outside the defined EVM boundary 30. Falling outside the defined boundary results in the sample being interpreted as an adjacent symbol or as undefined. Other ways of determining whether the location of the sampled symbol in IQ units falls outside the defined boundary may be used.

As more bits of information are represented, the density of symbols on the symbol constellation illustrated in FIG. 2 increases. Even small errors in the location of received symbols can impair the bit-level information derived from the sampled signal. In the design of these systems, the most important consideration is the ultimate delivery of information, which is transmitted through digital bits.

For design and validation purposes of these communications systems, especially those that have adaptive algorithms, like cognitive radios, designers may desire to tune the algorithms to adjust operating frequency at higher or lower levels of imposed data rate as a result of interference. A designer may desire to retain a very small EVM boundary that matches the expected interference or mission-criticality of losing link for the designer's given use case. One can imagine the severity of losing a communications link in a public safety situation, for example.

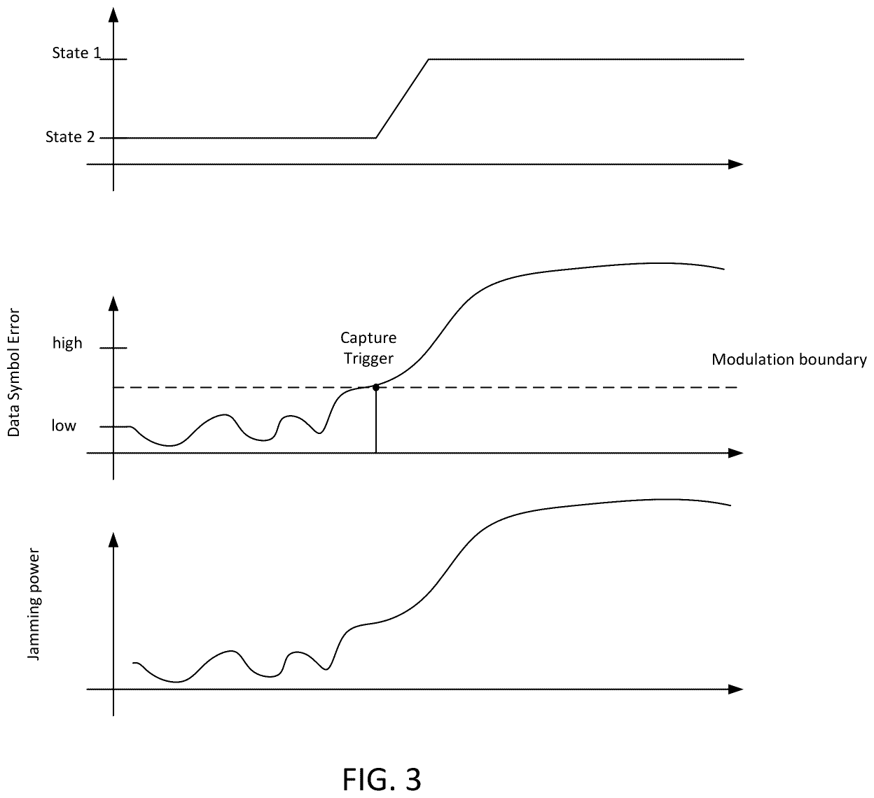

As illustrated in FIG. 3, the frequency of operation of the communications system may determine the ability of the system to communicate digital information. FIG. 3 shows the operation of the communication system at one state, which is commonly the frequency of the transmission, at the desired frequency, state 1, and then “jumps” to the second frequency at state 2, to avoid an impairment at the first frequency. This impairment may result from a jammer, such as jammer 18 in FIG. 1. The impairment of the ability to communicate, determined by the violation of the modulation boundary motivates the radio to adapt by shifting the radio operating frequency. The point at which boundary violation occurs also triggers the capture of the signal or samples of the signal from the observation receiver in order to analyze characteristics of the radio's response, such as latency or selected frequency.

The analysis of the captured samples allows the radio system of the transmitter and receiver to detect the interference and respond as quickly as possible to maintain the maximum information transfer possible in the radio system. Latency and selected frequency comprise two characteristics important to the analysis. As an example, without limitation, a receiver detects the symbol/bit errors and sends a “change” command to the sender. The transmitter and receiver then tune to the new frequency. This type of change, moving to a new frequency, represents one example, and the system may use other characteristics and make other changes.

In this test scenario above, a user might want to set the parameters to check in the analysis. These parameters may include the boundary, either a deviation boundary or the EVM, either in terms of a percentage or in decibels (dB), pre- and post-trigger sample quantity, and hysteresis, meaning the number of consecutive EVM boundary violations or a percentage (%) of violations within a given series of symbols.

The triggering capability provides a unique way to determine the point at which important performance characteristics are visible to the user of these cognitive systems. The triggering capability reduces the amount of data the user has to analyze, as well as the amount of data to be stored and later searched.

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### EXAMPLES

Illustrative examples of the disclosed technologies are provided below. An embodiment of the technologies may include one or more, and any combination of, the examples described below.

Example 1 is a test and measurement instrument, comprising: an antenna to receive signals containing symbols from a system under test (SUT); one or more analog-to-digital converters (ADC) to sample the signals received from the SUT; a memory to selectively store samples from the ADC; and one or more processors configured to execute code that causes the one or more processors to: receive samples from the ADC; analyze the samples from the ADC to determine whether one or more of the symbols received from the SUT has exceeded an expected modulation boundary for the one or more symbols; identifying a time at which the one or more symbols exceeded the expected modulation boundary as a trigger time; and store samples from a predetermined window of time surrounding the trigger time in the memory.

Example 2 is the test and measurement instrument of Example 1, wherein the expected modulation boundary comprises one or more of phase deviation, amplitude deviation, frequency deviation, and error magnitude.

Example 3 is the test and measurement instrument as claimed in either of claim 1 or 2, wherein the expected modulation boundary comprises one of user-selected, or in accordance with a standard.

Example 4 is the test and measurement instrument of any of Examples 1 through 3, the code that causes the one or more processors to analyze the samples for the SUT to determine whether the one or more symbols received from the SUT has exceeded the expected modulation boundary comprises code to also analyze performance characteristics of a response of the SUT to an impairment that caused the one or more symbols to exceed the expected modulation boundary.

Example 5 is the test and measurement instrument of Example 4, wherein the code that causes the one or more processors to analyze the performance characteristics of the samples comprises code that causes the one or more processors to determine one or more of a measure of by how much the symbol exceeded an error vector magnitude, quality of samples prior to and after a current symbol in time, and a number of consecutive boundary violations within a given series of samples.

Example 6 is the test and measurement instrument of any of Examples 1 through 5, wherein the code that causes the one or more processors to analyze the samples comprises code to analyze characteristics of the signals received from the SUT.

Example 7 is the test and measurement instrument of any of Examples 1 through 6, wherein the code that causes the one or more processors to analyze the samples from the SUT comprises code to cause the one or more processors to: convert the samples from the SUT to In-phase and Quadrature (IQ) components; and determine if the IQ components are located within a boundary around an expected location.

Example 8 is the test and measurement instrument of Example 7, wherein the code that causes the one or more processors to analyze the samples from the SUT comprises code to plot the IQ components on an I-Q plot to determine if the IQ components are located within the boundary.

Example 9 is a method, comprising: receiving a signal containing symbols from a system under test (SUT); converting the signal to digital samples; analyzing the digital samples from the SUT to determine whether one or more symbols received from the SUT has exceeded an expected modulation boundary for the one or more symbols; identifying a time at which the one or more symbols exceeded the expected modulation boundary as a trigger time; and store the digital samples from a predetermined window of time surrounding the trigger time in memory.

Example 10 is the method of Example 9, wherein the expected modulation boundary comprises one or more of phase deviation, amplitude deviation, frequency deviation, and error vector magnitude.

Example 11 is the method of either of Examples 9 or 10, wherein the expected modulation boundary comprises one of user-selected, or in accordance with a standard.

Example 12 is the method of any of Examples 9 through 11, wherein analyzing the digital samples to determine whether the one or more symbols received from the SUT has exceeded the expected modulation boundary comprises analyzing performance characteristics of the digital samples.

Example 13 is the method of Example 12, wherein analyzing the performance characteristics of the digital samples comprises one or more of determining by how much the one or more symbols exceeded an error vector magnitude, a quality of samples prior to and after a current symbol in time, and a number of consecutive boundary violations within a given series of samples.

Example 14 is the method of any of Examples 9 through 13, wherein analyzing the digital samples comprises analyzing characteristics of the signal received from the SUT.

Example 15 is the method of any of Examples 9 through 14, wherein analyzing the digital samples from the SUT comprises: converting the digital samples from the SUT to In-phase and Quadrature (IQ) components; and determining if the IQ components are located within the expected modulation boundary around an expected location.

Example 16 is the method of Example 15, further comprising plotting the IQ components on an I-Q plot.

Additionally, this written description makes reference to particular features. It is to be understood that the disclosure in this specification includes all possible combinations of those particular features. Where a particular feature is disclosed in the context of a particular aspect or example, that feature can also be used, to the extent possible, in the context of other aspects and examples.

Also, when reference is made in this application to a method having two or more defined steps or operations, the defined steps or operations can be carried out in any order or simultaneously, unless the context excludes those possibilities.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Although specific examples of the invention have been illustrated and described for purposes of illustration, it will be understood that various modifications may be made without departing from the spirit and scope of the invention. Accordingly, the invention should not be limited except as by the appended claims.

1. A test and measurement instrument, comprising:
an antenna to receive signals containing symbols from a system under test (SUT);
one or more analog-to-digital converters (ADC) to sample the signals received from the SUT;
a memory to selectively store samples from the ADC; and
one or more processors configured to execute code that causes the one or more processors to:
receive samples from the ADC;
analyze the samples from the ADC to determine whether one or more of the symbols received from the SUT has exceeded an expected modulation boundary for the one or more symbols;
identifying a time at which the one or more symbols exceeded the expected modulation boundary as a trigger time; and
store samples from a predetermined window of time surrounding the trigger time in the memory.

2. The test and measurement instrument as claimed in claim 1, wherein the expected modulation boundary comprises one or more of phase deviation, amplitude deviation, frequency deviation, and error magnitude.

3. The test and measurement instrument as claimed in claim 1, wherein the expected modulation boundary comprises one of user-selected, or in accordance with a standard.

4. The test and measurement instrument as claimed in claim 1, the code that causes the one or more processors to analyze the samples for the SUT to determine whether the one or more symbols received from the SUT has exceeded the expected modulation boundary comprises code to also analyze performance characteristics of a response of the SUT to an impairment that caused the one or more symbols to exceed the expected modulation boundary.

5. The test and measurement instrument as claimed in claim 4, wherein the code that causes the one or more processors to analyze the performance characteristics of the samples comprises code that causes the one or more processors to determine one or more of a measure of by how much the symbol exceeded an error vector magnitude, quality of samples prior to and after a current symbol in time, and a number of consecutive boundary violations within a given series of samples.

6. The test and measurement instrument as claimed in claim 1, wherein the code that causes the one or more processors to analyze the samples comprises code to analyze characteristics of the signals received from the SUT.

7. The test and measurement instrument as claimed in claim 1, wherein the code that causes the one or more processors to analyze the samples from the SUT comprises code to cause the one or more processors to:
convert the samples from the SUT to In-phase and Quadrature (IQ) components; and
determine if the IQ components are located within a boundary around an expected location.

8. The test and measurement instrument as claimed in claim 7, wherein the code that causes the one or more processors to analyze the samples from the SUT comprises code to plot the IQ components on an I-Q plot to determine if the IQ components are located within the boundary.

9. A method, comprising:
receiving a signal containing symbols from a system under test (SUT);
converting the signal to digital samples;
analyzing the digital samples from the SUT to determine whether one or more symbols received from the SUT has exceeded an expected modulation boundary for the one or more symbols;
identifying a time at which the one or more symbols exceeded the expected modulation boundary as a trigger time; and
store the digital samples from a predetermined window of time surrounding the trigger time in memory.

10. The method as claimed in claim 9, wherein the expected modulation boundary comprises one or more of phase deviation, amplitude deviation, frequency deviation, and error vector magnitude.

11. The method as claimed in claim 9, wherein the expected modulation boundary comprises one of user-selected, or in accordance with a standard.

12. The method as claimed in claim 9, wherein analyzing the digital samples to determine whether the one or more symbols received from the SUT has exceeded the expected modulation boundary comprises analyzing performance characteristics of the digital samples.

13. The method as claimed in claim 12, wherein analyzing the performance characteristics of the digital samples comprises one or more of determining by how much the one or more symbols exceeded an error vector magnitude, a quality of samples prior to and after a current symbol in time, and a number of consecutive boundary violations within a given series of samples.

14. The method as claimed in claim 9, wherein analyzing the digital samples comprises analyzing characteristics of the signal received from the SUT.

15. The method as claimed in claim 9, wherein analyzing the digital samples from the SUT comprises:
converting the digital samples from the SUT to In-phase and Quadrature (IQ) components; and
determining if the IQ components are located within the expected modulation boundary around an expected location.

16. The method as claimed in claim 15, further comprising plotting the IQ components on an I-Q plot.
